(19) United States
(12) Patent Application Publication
(10) Pub. No.: US 2007/0279845 A1
(43) Pub. Date: Dec. 6, 2007

(54) Corrosion Protection for Pressure Sensors

(76) Inventors: Winfried Kuhnt, Stuttgart (DE); Wilfried Ihl, Sachsenheim (DE); Andreas Junger, Reutlingen (DE); Hubert Benzel, Pliezhausen (DE); Markus Muzic, Murr (DE); Lutz Mueller, Aichtal (DE); Frank Schaefer, Tuebingen (DE); Roland Guenschel, Reutlingen (DE); Marco Holst, Stuttgart (DE); Frank Wehrmann, Reutlingen (DE); Polichronis Lepidis, Reutlingen (DE); Gabriele Godzik, Hambuehren (DE); Kristin Weinert, Wendlingen (DE)

Correspondence Address: KENYON & KENYON LLP, ONE BROADWAY, NEW YORK, NY, 10004, US

(21) Appl. No.: 10/588,219

(22) PCT Filed: Feb. 7, 2005
(86) PCT No.: PCT/EP05/50503

§ 371 Date: May 7, 2007

(30) Foreign Application Priority Data
Feb. 9, 2004 (DE) 102004006212.9
Mar. 27, 2004 (DE) 102004015123.7
Jul. 10, 2004 (DE) 102004033475.7

(51) Int. Cl. G01D 11/24; H05K 7/00

(52) U.S. Cl. 361/679; 264/272.11

(57) ABSTRACT

The present invention describes a device having a housing and at least one electrical component, the housing having at least one of the electrical components and being filled at least partially by a passivating agent. Furthermore, it is provided that the electrical component is covered at least partially by the passivating agent. Now, the crux of the present invention is that an additional material layer is applied on top of the passivating agent. Using this additional material layer, a device is able to be implemented in a simple and cost-effective construction, that is resistive to environmental damages. This makes possible using electrical components in corrosive environments.

### FIELD OF THE INVENTION

The present invention relates to a micromechanical pressure sensor and a method for manufacturing a micromechanical pressure sensor, in which a sensor element in a housing is covered by a passivating agent.

### BACKGROUND INFORMATION

For the protection of a sensor from damaging environmental influences, the sensor element is able to be covered using a special passivating layer. This is done in such a way, for example, that the sensor element or the (electrical and/or mechanical) components required for detecting and/or evaluating a sensor signal are mounted in a housing and are subsequently covered by a passivating agent. Usually this passivation is achieved by filling the housing. The filling in this context is used to passivate the sensor element or to protect the components against media such as water, air, gasoline, salt etc.

Thus it is possible to prevent sensitive elements of the sensor from corroding. What is problematic about the passivation, however, is the interaction of the passivating agent and the damaging medium.

Micromechanical pressure sensors, in which, for system-related reasons, the pressure is supplied from the front side of the sensor chip, are normally protected from environmental influences by a gel such as, for example, a fluorosilicone gel. This gel covers the surface of the chip and the bonding wires and prevents corrosive media from coming into contact with the chip. When selecting the gel, however, one must be mindful of the fact that the gel transmits the pressure of the medium for detecting a pressure variable to the pressure sensor diaphragm in the sensor chip.

For the application of pressure sensors in a highly corrosive environment, as can, for instance, be found in the exhaust branch of a motor vehicle, even the best of the currently available gels cannot prevent corrosive components of the medium from diffusing through the gel over time and resulting in corrosion of the sensor element or of other components on the sensor chip.

An expensive structural variant for protecting the pressure sensor is to install the sensor element made up of a sensor chip and bonding wires in a chamber filled with silicone oil, which maintains contact with the surroundings via a steel diaphragm. A change of the ambient pressure is transmitted via the steel diaphragm directly to the silicone oil and thus to the sensor element or the sensor chip.

In order to increase the protective action of the passivating gel, it is known that one may admix to the passivating gel a chemical buffer in the form of low acid and/or alkali quantities, in response to which the pH value in the passivating gel is held constant to the greatest extent, and thereby the service life of the sensor element is prolonged. If buffers made up of a mixture of acid-binding and alkali-binding substances are used, then, in response to an appropriate environment, in each case only one of the two components is active, whereas the other half of the mixture does not contribute to the protective effect.

### SUMMARY

The present invention provides a device having a housing and at least one electrical component, the housing having at least one of the electrical components being filled at least partially with a passivating agent. Furthermore, it is provided that the electrical component is covered at least partially with passivating agent. The present invention provides that an additional material layer is applied on top of the passivating agent. Using this additional material layer, a device is able to be implemented in a simple and cost-effective construction, that is resistive to environmental damages. This makes possible using electrical components in corrosive environments.

In one example embodiment of the present invention, it is provided that the electrical component has especially a micromechanical sensor element. In this context, the micromechanical sensor element is able to record a pressure variable, a temperature variable, an air mass, a resistance variable and/or a concentration of at least one medium. A medium favorably surrounds at least a part of the device and/or of the micromechanical sensor element, in this instance.

What is particularly advantageous in this context is that, because of the selection of the passivating agent in combination with the material of the additional material layer, an optimized sealing of the electrical component or of the sensor element is achieved. Consequently, damage to the sensor element by corrosive media can be prevented. In addition to that, because of the construction according to the present invention, use of the pressure sensor is also possible in liquid media, since the material of the additional material layer is selected so that the liquid medium is separated from the passivating agent.

Beyond that, the electrical component, and especially the sensor element, has areas that are sensitive to corrosion. These may be, for example, contacting surfaces or elements such as bonding pads and/or bonding wires. Therefore, at least these areas that are sensitive to corrosion are covered with the passivating agent.

In one example embodiment of the present invention, the surrounding medium is separated from the passivating agent by the additional material layer. However, it may also be advantageously provided that the additional material layer protects against the corrosive components of the surrounding medium, which would otherwise corrode the electrical components, by an appropriate chemical reaction. A further possibility of increasing the service life of the electrical components, and thus the duration of utilization of the sensor, is to reduce the diffusion speed of the corrosive components of the surrounding medium, using suitable materials. It has proven to be particularly advantageous to use corrosion resisting materials and/or materials impervious to water in the additional material layer.

The additional material layer may be developed as a diaphragm layer, it being possibly provided that the diaphragm layer has a wave-shaped surface structure. This wave-shaped surface structure is able to compensate for a temperature-conditioned expansion of the passivating agent, without there being a crack in the diaphragm layer.

In a further refinement of the present invention, fluorosilicone gel is provided as the passivating agent and/or a layer made of a corrosion resistant material and/or a material that is impervious to water is provided as the additional material layer, such as teflon or a parylene. Furthermore, in an example embodiment of the present invention, it is provided that the passivating agent and the material of the additional material layer have temperature coefficients of expansion that are adjusted to reach other.

It is provided that the housing, in which the sensor is mounted, has a lower part of the housing having housing walls. In this context, the lower part of the housing is advantageously filled with the passivating agent up to the structural height of the housing walls.

In addition, in a further embodiment of the present invention, it is provided that the housing has an upper part of the housing having a housing cover. This housing cover, in this instance, may be the housing in such a way that it fixes the additional material layer on the passivating agent. It may be provided, in this context, that the housing cover is set upon the passivating agent only after applying the additional material layer. However, it is also conceivable that the additional material layer is applied directly into the housing cover, and that it covers the passivating agent only after the placing of the housing cover onto lower part of the housing.

In order to make possible the passing on of the pressure change of the medium to the sensor element, an opening is provided in the housing cover through which the medium is able to get in contact with the additional material layer.

It is provided, advantageously, to cover the electrical contacting surface and/or the electrical contacting element using at least one specifiable layer thickness of the passivating agent. Thus, it may be provided to apply the passivating agent over at least one bonding pad and/or one bonding wire at a thickness of at least 0.2 mm. It may be achieved by such a specifiable layer thickness of the passivating agent that components of the medium that trigger the corrosion do not reach, or reach with a time delay the areas that are susceptible to corrosion.

One possibility of reducing the speed at which the medium, or rather the components of the medium, penetrate into the passivating agent is to introduce, as an additional material layer, plate-like fillers such as mica foil into the passivating agent. Besides that, however, it is also conceivable to add plate-like fillers such as hydrotalcite, magnesium hydroxide, aluminum hydroxide, hydromagnesite or huntite to the passivating agent, in order to decrease the speed of diffusion and/or lengthen the diffusion path.

However, it may also be provided to render harmless the corrosive components of the medium which are able to diffuse into the passivating agent, by a suitable chemical reaction (neutralization or adsorption). Thus, for example, amino functionalized siloxanes are available as material for the additional material layer, in which the aminopropyl groups react as bases with corrosive acids to form ionic bonds. Acids may also be bound by monoalkylamines, dialkylamines or trialkylamines, silazanes or amino-terminated silicone oil or acid-binding fillers such as hydrotalcite, magnesium hydroxide, aluminum hydroxide or hydromagnesite.

Generally, it may be provided that the device represents an especially micromechanical sensor, for instance, for recording a pressure variable that represents the pressure of a surrounding medium. But beyond that, it is also conceivable that the device records a relative pressure variable of two media. Because of the embodiment according to the present invention, the use of such a pressure sensor in the exhaust gas stream or in the tank of a motor vehicle is possible. However, it is also conceivable, beyond this, that the device might represent a (hot) air mass sensor or a generator control device.

By a suitable selection of the passivating agent and the materials for the additional material layer, it is further possible to reduce the shaking stress of gel-treated bonding wires. Thus, for example, an inflexible barrier layer is able to reduce shift amplitudes of the passivating gel.

In using the sealing of the passivating agent according to the present invention, it is possible to eliminate hermetic housings or housings that are impervious to spray, which are installed to protect the gel spaces in electrical and/or electronic components. Moreover, because of the use of such sealing, one may consider again using oil-exuding gels in electronic components that are not supposed to come into contact with volatile, bleeding components of a passivating gel.

Using the embodiment of the device according to the present invention, a greater effectiveness of passivation with respect to the corrosive environment may be achieved compared to the addition of buffers, that is, acid or alkali binding substances.

By adding fillers to the passivating gel, the swelling up of the gel due to solvents contained in the exhaust gas can be reduced.

Organic, acid-binding fillers, having an optical refractive index adapted to the passivating gel (e.g. the combination silicone gel/polyamide), make possible optical analysis of the gel-treated sensor elements according to the present invention, because of lower optical scattering caused by small differences in the refractive indices.

### BRIEF DESCRIPTION OF THE DRAWINGS

FIG. 1 shows a conventional micromechanical pressure sensor in a housing.

FIG. 2 shows a first example embodiment of the present invention.

FIG. 3 shows a second example embodiment of the present invention.

FIG. 4 shows another example embodiment of the present invention.

### DETAILED DESCRIPTION

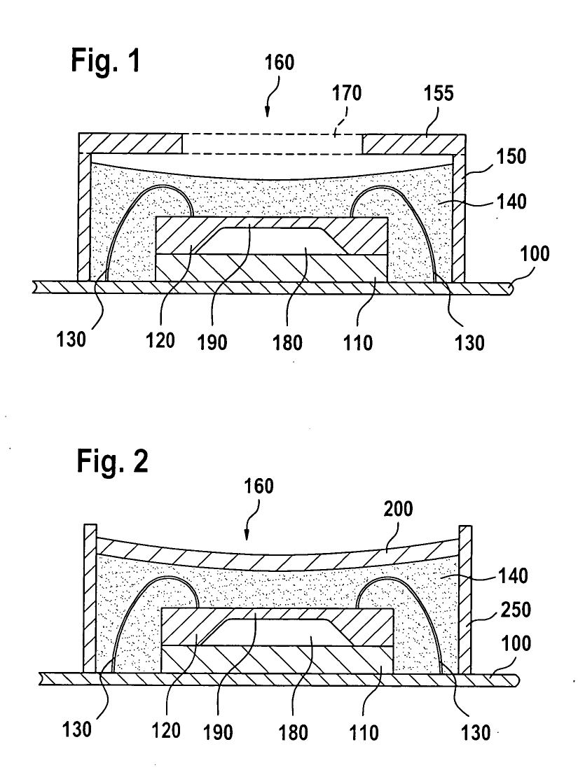

In FIG. 1, which shows a conventional structure of a micromechanical pressure sensor in a housing, a micromechanical sensor element, made up, for instance, of a substrate 110 and a sensor chip 120, is applied onto a carrier element 100. However, the sensor element can also be implemented by another construction. Common materials for the micromechanical sensor element are semiconductor materials or steels, in this instance. Ceramics or printed circuit boards are used as carrier element 100, for example. Sensor chip 120 may be furnished, for example, with a diaphragm 190 and a cavity 180 having a specified pressure. However, it may also be provided that substrate 110 and carrier element 100 have a lead-through to diaphragm 190 for differential pressure applications. A pressure difference prevails between the pressure in cavity 180 and the ambient pressure of the sensor. A variation in the ambient pressure is thus expressed in a movement of diaphragm 190. With the aid of suitable electrical components such as, for example, piezoelectric resistors (not shown) on diaphragm 190, this movement can be converted into a measured variable that is generated proportionally to the occurring pressure difference. For transmitting this measured variable, connecting elements such as bonding wires 130 are provided, which are routed from sensor chip 120 to support element 100 for the further evaluation of the measured variable. Usually, these bonding wires 130 are fastened to sensor chip 120 and/or to carrier element 100 with the aid of bonding pads. It is also conceivable, however, to provide contacting surfaces on sensor chip 120 and/or on carrier element 100, which allow for a control of sensor chip 120 and/or an evaluation or transmission of the measured variable.

To protect the sensor element against damage, the sensor element is accommodated in a housing. To this end, as shown in FIG. 1, the housing may be made up merely of housing walls 150, or a combination of housing walls 150 and a housing cover 155. In order for the sensor element or diaphragm 190 to be able to record the pressure difference from the surroundings, it is provided that housing cover 155 have an opening 170, through which the medium can act upon diaphragm 190. Since the contacting locations of the bonding wires and/or the further electrical components of the sensor element represent areas that are sensitive to corrosion, it is provided to fill up the internal space of housing 150 and 155 using a passivating agent 140, such as a gel. When selecting passivating agent 140, care must be taken to ensure that all corrosion-sensitive areas are sufficiently covered so that they are protected against the possibly corrosive medium. In addition, passivating agent 140 must be selected in such a way that, on the one hand, it is sufficiently soft so as not to cause mechanical strains on sensor diaphragm 190, but that, on the other hand, it also transmits the ambient air pressure, that acts in direction 160, directly to diaphragm 190.

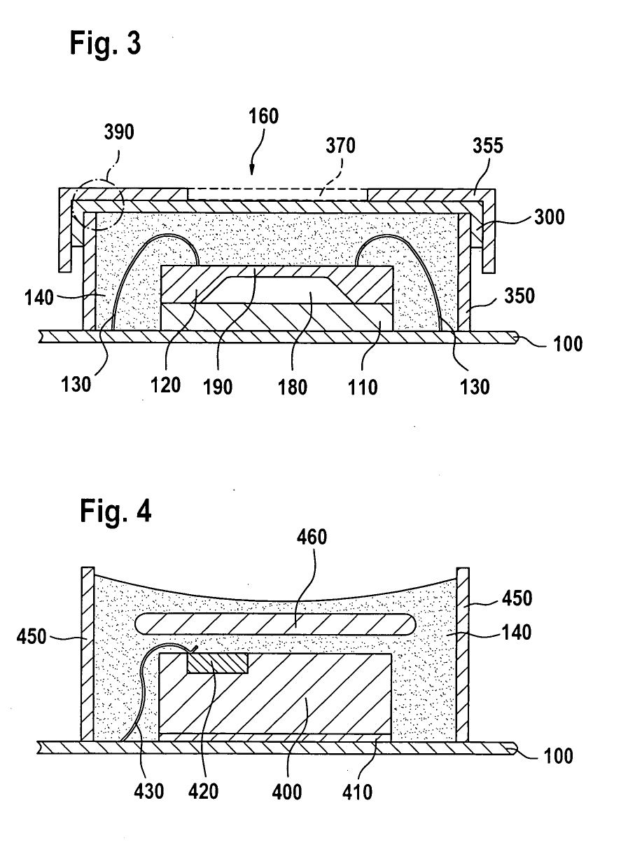

In strongly corrosive environments, such as for instance in the exhaust gas branch of an internal combustion engine, even the best currently available passivating gel is not able to protect the pressure sensor chip sufficiently from corrosion. Therefore, in accordance with the present invention, in addition to the passivating gel, a further material layer is applied directly onto the gel, as shown in FIGS. 2 and 3.

FIG. 2 shows the housing of a pressure sensor which is implemented by housing walls 250. As was shown in FIG. 1, the sensor element and bonding wires 130 are covered by a passivating agent 140. It is advantageously provided that all elements both of the sensor element and of the connecting elements are completely covered, although this is not an absolute necessity. The only required measure is the covering of the areas that are sensitive to corrosion. Advantageously, a minimum thickness of the covering is provided, in this context, in order to make possible sufficient protection of the area sensitive to corrosion from the corrosion-triggering components of the ambient medium. An additional material layer 200 is subsequently applied to passivating agent 140, that was introduced into housing 250, which covers the entire surface of passivating agent 140. This may be done in the form of a diaphragm, for example. Using such a covering of passivating agent 140, it is prevented that the medium comes into contact with passivating agent 140. When selecting the material of additional material layer 200, one should observe that layer 200 should be sufficiently flexible to pass on the ambient pressure directly onto the gel. For this reason it is also advantageous if there is no air between the gel and the diaphragm, since otherwise the enclosed air could expand in response to temperature increases, and could lead to an undesired and interfering pressure signal. Furthermore, the material of layer 200 should be selected in such a way that it allows no corrosive media, but also no water, the diaphragm itself having to withstand the media and an expansion of passivating agent 140 conditioned upon temperature. Compensation for the temperature-conditioned expansion of passivating agent 140 is also possible by an appropriate surface structuring of layer 200, for instance, in a wave pattern.

Teflon is available as a possible material for layer 200, because of its favorable properties. Moreover, in one example embodiment, layer 200 may be developed from a parylene, or at least contain some of it. Parylenes are substituted or unsubstituted polyparaxylenes or poly-[2,2]-paracyclophanes. Halogens, such as fluorine, chlorine and bromine particularly come into consideration as substituants, the parylenes being able to be mono-, di-, tri- or tetra-substituted. Layer 200 is developed to have a layer thickness of 1 to 50 μm.

As examples, silicone gels, for instance, based on polydimethylsiloxane (PDMS) or polyphenylmethylsiloxane, are used, or (per)fluorinated silicone gels, such as perfluorinated PDMS. Furthermore, gel systems are suitable that are based on possibly (per)fluorinated polyethers or vinyl polymers that contain cross-linking agents with hydridic siloxane units, fillers, possibly thixotropic agents, adhesion promoters, inhibitors and catalysts.

However, deviating from the illustration in FIG. 2, it may also be provided that passivating agent 140 can be filled up to the maximum height of housing walls 250. In this instance, however, it should be observed that additional layer 200 has to cover the entire surface of passivating agent 140, in order to yield optimum protection or optimum sealing. One possibility of achieving such covering is shown in FIG. 3. In this representation, the sensor element is filled with passivating agent 140 up to the height of housing wall 350. Thereafter, an additional material layer 300 is applied onto the housing thus filled which, besides passivating agent 140, also covers parts of housing walls 350. The overlapping of the covering of housing walls 350 by material layer 300 is necessary to prevent edge effects that could be generated in response to an insufficient covering of the passivating agent in region 390. In an unfavorable case, these edge effects could otherwise lead to penetration of the medium into passivating agent 140 and to damage of the sensor element. After the application of layer 300, optionally, an upper housing part conceived as a cover 355 can be firmly applied, which clamps in and fixes layer 300 on the housing's lower part 350. If necessary, cover 355 may be welded or adhered to the part 300. An opening 370 in cover 355 makes it possible to let the pressure of the medium act on diaphragm 190 in the direction 160.

In a further exemplary embodiment, additional layer 300 is introduced directly into cover 355, before the cover is applied onto housing lower part 350 that is filled with passivating agent 140.

Because of the configuration of the pressure sensor according to the present invention, the sensor is suitable for both gaseous and for liquid media. In this connection, additional material layer 200 or 300 offers a protection that the passivating agent by itself is not able to offer. Thereby, pressure sensors that are produced surface-micromechanically are able to be used in liquid media.

FIG. 4 shows an additional exemplary embodiment, which represents the protection of a sensor element 400, an evaluation circuit 420 and a bonding connection 430. Usually, sensor element 400 is applied with the aid of an adhesive or a solder onto carrier element 100. A housing wall 450 and a gel ring make possible the filling of the internal space and the covering of sensor element 400 with an appropriate passivating agent 140, additional material layer 460 being applied directly into passivating agent 140, according to FIG. 4. In this context there is the possibility that passivating agent 140 is filled in first of all, before additional material layer 460 is introduced. This may be done, for instance, by applying a platelet, onto passivating agent 140 that has not yet gelled, which sinks down during the curing process. Of course, it may also be provided that the platelet is only laid on the surface of passivating agent 140, and stays there. In addition, there is the possibility of generating additional material layer 460 by mixing in the additional material into passivating agent 140. Thus, for example, cross-linking of the materials introduced may be achieved during the curing or further special treatment of the sensor. However, it is also conceivable to use appropriate solvents during diffusion of the material to form the additional layer, during the production of the sensor. Alternatively, the additional material may be polymerized into the network generated using the passivating gel. Filler concentrations of 28 to 50 weight-% of the additional material are conceivable. In special cases, an overall filler concentration of 38 to 40 weight-% may also be provided.

Additional material layer 460, according to the example in FIG. 4, may be selected in such a way that it lengthens the diffusion path of the corrosive components of the medium, which penetrate into the passivating agent and destroy the areas that are sensitive to corrosion. This happens in that the material selected for this lowers the diffusion speed. For such a lengthening of the diffusion path of the corrosive components, platelet-shaped fillers such as mica platelets or materials such as hydrotalcite, magnesium hydroxide, aluminum hydroxide, hydromagnesite or huntite are available. In this context, magnesium hydroxide represents a nontoxic flameproofing agent that is stable to high temperatures which, at the same time, acts as an acid binder. The hydrotalcite may be used as a layer-formed, basic magnesium-aluminum-hydroxy carbonate. All the fillers mentioned that lengthen the diffusion path, with the exception of mica platelets, are bases as well (however, not buffers), which neutralize acids that are diffusing in. Even inert, particle-shaped fillers, such as silica particles (aerosil) act as diffusion path lengtheners, at greater filler contents.

Corrosive agents that diffuse in, from which the electrical or electronic components have to be protected, may contain, for example,
hydrochloric acid,
nitric acid,
sulfuric acid,
carboxilic acids,
alcohols,
aldehydes or
ammonia.

In this context, the agents may attack the sensor both in gaseous form or as a condensate.

Besides the lengthening of the diffusion path, it may also be provided to develop the additional material layer using a material which renders the corrosive agents or components of the medium harmless, with the aid of a chemical reaction. Since the electrical and/or electronic components are attacked primarily by acid-containing components of the medium, in one example embodiment according to the present invention it is provided to fortify the material layer and/or the passivating agent with basic compounds. This is done, for instance, by using amino-functionalized siloxanes, the aminopropyl groups contained therein reacting with the acid while forming slats. In this instance, it is also advantageous that amino-functionalized siloxanes are able to be polymerized into the passivating agent. A further possibility is the use of highly viscous amino-terminated silicone oil, which also binds acids to form salts. Silazanes such as Fluorochem PS112, a cross-linked poly(1,1-dimethylsilazane), have a similar function.

Besides the materials mentioned so far for additional material layer 200, 300 and 460, acetamides, such as bis/trimethylsilylacetamide, may also be used which are able to react with alcohols, phenols and acids. A similar effect is achieved using carbamates such as N,O-bis(trimethylsilyl). However, in addition, organic bases such as polyethylenimines, polyamines or polyamides (PA6.6, PA11, PA6, PA3.6, etc.) are conceivable as components of the additional material layer. In this context, the compounds named may also be introduced in the form of fibers.

Fillers hydrotalcite, magnesium hydroxide, aluminum hydroxide, hydromagnesite and calcium carbonate are effective as acid binders, besides their effect in lengthening the diffusion path.

Possible protective layers may be formed by plasma polymerization of silicoorganic substances, e.g., hexamethyldisilazane (HMDS-N), hexamethyldisiloxane (HMDS-O), hexamethyldisilane (HMDS), bis-(trimethylsilyl)methane, decamethylcyclopentasiloxane, octamethyltrisiloxane, dimethylcyclosiloxanes of diverse chain lengths, methylphenylcyclosiloxanes of diverse chain lengths, dimethyldimethoxysilane, short-chained perfluoropolyethers, octamethylcyclotetrasilazane, octaphenylcyclotetrasiloxane or parylenes.

1-17. (canceled)

18. A device, comprising:
at least one electrical component;
a housing containing the at least one electrical component and at least partially filled by a passivating agent, wherein the at least one electrical component is at least partially covered by the passivating agent; and
an additional material layer applied on the passivating agent.

19. The device as recited in claim 18, wherein the at least one electrical component has a micromechanical sensor element, and wherein the micromechanical sensor element detects at least one of a pressure variable, a temperature variable, an air mass, a resistance variable, and a concentration of at least one medium surrounding at least one of the device and the micromechanical sensor element.

20. The device as recited in claim 18, wherein the at least one electrical component includes at least one area that is sensitive to corrosion, and wherein the at least one area that is sensitive to corrosion is covered by the passivating agent.

21. The device as recited in claim 18, wherein the additional material layer includes a material that is at least one of resistant to corrosion and impervious to water, and wherein the additional material at least one of: a) separates the passivating agent from an ambient medium; b) reduces a speed of diffusion of the ambient medium in the passivating agent; and c) renders harmless a corrosive component of the ambient medium by a chemical reaction.

22. The device as recited in claim 18, wherein the additional material layer is configured as a diaphragm layer having a wave-shaped surface structure.

23. The device as recited in claim 21, wherein at least one of: a) the passivating agent includes a fluorosilicone gel; and b) the additional material layer includes one of teflon and parylene.

24. The device as recited in claim 21, wherein the passivating agent and the additional material layer have at least one of: a) substantially equivalent temperature coefficients of expansion; and b) substantially equivalent optical indices of refraction.

25. The device as recited in claim 21, wherein the housing includes a housing lower part having housing walls, and wherein the housing lower part is filled with the passivating agent up to the height of the housing walls.

26. The device as recited in claim 21, wherein the housing includes a housing upper part having a housing cover, and wherein the housing cover has an opening and fixes the additional material layer onto the passivating agent.

27. The device as recited in claim 20, wherein the at least one area that is sensitive to corrosion includes at least one of an electrical contacting surface and an electrical contacting element, and wherein the at least one area that is sensitive to corrosion is covered by a layer of the passivating agent having a layer thickness of more than 0.2 mm.

28. The device as recited in claim 21, wherein, for reducing the speed of diffusion of the ambient medium in the passivating agent, the additional material layer includes one of: a mica platelet; hydrotalcite; magnesium hydroxide; aluminum hydroxide; hydromagnesite; and huntite.

29. The device as recited in claim 21, wherein, for rendering harmless a corrosive component of the ambient medium by a chemical reaction, the additional material layer includes one of: amino-functionalized siloxanes; silazanes; a viscous amino-terminated silicone oil; monoalkylamines; dialkylamines; trialkylamines; hydrotalcite; magnesium hydroxide; aluminum hydroxide; hydromagnesite; huntite; poly(1,1-dimethylsilazane); polyamines; and polyamides, and wherein the siloxanes, the poly(1,1-dimethylsilazane), the polyamines and the polyamides have a fiber shape in the material layer.

30. The device as recited in claim 28, wherein the additional material layer has a filler concentration of 28 to 50 weight-%.

31. The device as recited in claim 29, wherein the additional material layer has a filler concentration of 28 to 50 weight-%.

32. The device as recited in one of claim 21, wherein the device is one of: a) a micromechanical pressure sensor for recording a pressure variable representing one of a pressure of the ambient medium and a pressure difference between two components of the ambient medium; b) a hot air mass sensor; and c) a generator control device.

33. A method for manufacturing a device, comprising:
providing a housing;
providing at least one electrical component in the housing;
at least partially filling the housing with a passivating agent, wherein the at least one electrical component is at least partially covered by the passivating agent; and
applying an additional material layer on the passivating agent.

34. The method as recited in claim 33, further comprising:
providing, before the filling of the housing with the passivating agent, at least one of an electrical contacting surface and an electrical contacting element, wherein the at least one of the electrical contacting surface and the electrical contacting element at least one of: a) has a bonding pad; b) has a bonding wire; and c) is covered by the passivating agent.

35. The method as recited in claim 34, wherein the at least one of the electrical contacting surface and the electrical contacting element is covered by a layer of the passivating agent having a thickness of more than 0.2 mm over at least one of the bonding pad and the bonding wire.
